(19) United States
(12) Patent Application Publication
(10) Pub. No.: US 2026/0126722 A1
(43) Pub. Date: May 7, 2026

(54) EXPANDABLE NEGATIVE PHOTORESIST WITH SUSPENSION MATERIAL AND METHOD FOR REDUCING HORN SHAPES IN SPACER OXIDE USING EXPANDABLE NEGATIVE PHOTORESIST

(71) Applicant: NANYA TECHNOLOGY CORPORATION, NEW TAIPEI CITY (TW)

(72) Inventors: TZU-YU CHOU, NEW TAIPEI CITY (TW); CHIH-YING TSAI, NEW TAIPEI CITY (TW)

(21) Appl. No.: 18/976,450

(22) Filed: Dec. 11, 2024

Related U.S. Application Data
(63) Continuation of application No. 18/934,430, filed on Nov. 1, 2024.

(51) Int. Cl. G03F 7/00; G03F 7/38

(52) U.S. Cl. CPC G03F 7/0035; G03F 7/38

(57) ABSTRACT

The present application discloses an expandable negative photoresist and a method for adjusting a profile of a spacer oxide using the expandable negative photoresist. The expandable negative photoresist includes a polymer material, a suspension material and a photoacid generator. The suspension material contains a plurality of expandable molecules. An expansion coefficient of the suspension material is greater than that of the polymer material.

### CROSS-REFERENCE TO RELATED APPLICATION

This application is a continuation application of U.S. Non-Provisional application Ser. No. 18/934,430 filed Nov. 1, 2024, which is incorporated herein by reference in its entirety.

### TECHNICAL FIELD

The present disclosure relates to a negative photoresist and a method for adjusting a profile of a spacer oxide, and more particularly, to an expandable negative photoresist with a suspension material and a method for reducing horn shapes in spacer oxide using the expandable negative photoresist.

### DISCUSSION OF THE BACKGROUND

Semiconductor devices are used in various electronic applications, including personal computers, cellular telephones, digital cameras, and other electronic equipment. Sizes of semiconductor devices are continuously decreasing to meet growing demands for computing power. However, such scaling down presents challenges that are becoming more frequent and impactful. Therefore, there are still challenges to improving quality, yield, performance and reliability while reducing complexity.

Spacers and spacer oxides are commonly used in the manufacturing process of semiconductor devices to ensure correct distances between and functionality of components. With requirements for smaller line widths and spacings, such as critical dimensions (CD) less than 50 nm, and more complex fabrication processes, including pitch doubling and multiple patterning, ensuring the functional integrity of spacers while avoiding horn shapes remains an ongoing challenge.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides an expandable negative photoresist comprising a polymer material, a suspension material, and a photoacid generator (PAG). The suspension material contains a plurality of expandable molecules.

In some embodiments, an expansion coefficient of the suspension material is greater than that of the polymer material.

In some embodiments, a density of the suspension material is less than that of the polymer material.

In some embodiments, the expandable molecule is chemically bonded to the polymer material through a chemical bond.

In some embodiments, the chemical bond is severed using a photolytic bond cleavage method.

In some embodiments, the polymer material includes poly(tert-butoxycarboxystyrene) (PBOCSt).

In some embodiments, the PAG includes triphenylsulfonium hexafluoroantimonate (Ph₃SSbF₆).

Another aspect of the present disclosure provides a method for adjusting a profile of a spacer oxide, comprising providing a substrate, applying an underlayer over the substrate, forming a first photoresist layer over the underlayer, performing an exposure process on the first photoresist layer to create a second photoresist layer in the first photoresist layer, conducting a developing process on both the first and second photoresist layers to form a third photoresist layer and an expandable layer over the third photoresist layer, depositing a spacer oxide layer that covers both the third photoresist layer and the expandable layer, and performing a thermal process on the expandable layer, thereby adjusting the profile of the spacer oxide. The first photoresist layer comprises a first suspension material that contains a plurality of first expandable molecules, while the second photoresist layer comprises a second suspension material that contains a plurality of second expandable molecules. The expandable layer comprises the plurality of second expandable molecules. The thermal process is performed by activating the second expandable molecules in the expandable layer.

In some embodiments, the first photoresist layer is a negative-tone photoresist.

In some embodiments, the first suspension material is uniformly distributed throughout the first photoresist layer.

In some embodiments, each of the plurality of first expandable molecules is chemically connected to a first polymer material in the first photoresist layer through a chemical bond.

In some embodiments, an expansion coefficient of the first suspension material is greater than that of the first polymer material.

In some embodiments, a density of the first suspension material is less than that of the first polymer material.

In some embodiments, the first polymer material of the first photoresist layer includes poly(tert-butoxycarboxystyrene) (PBOCSt).

In some embodiments, each of the plurality of second expandable molecules is separate from a second polymer material in the second photoresist layer.

In some embodiments, an expansion coefficient of the second suspension material is greater than that of the second polymer material.

In some embodiments, a density of the second suspension material is less than that of the second polymer material.

In some embodiments, the second polymer material of the second photoresist layer includes poly(4-hydroxystyrene) (PHOSt).

In some embodiments, the third photoresist layer is free of the second expandable molecules, while the expandable layer contains the second expandable molecules.

In some embodiments, the method further comprises disposing a mask over the first photoresist layer, wherein the mask includes an unmasked portion that defines a region of the first photoresist layer to be subsequently exposed.

In some embodiments, the exposure process is performed using an ultraviolet (UV) light.

In some embodiments, the first photoresist layer also includes a photoacid generator (PAG).

In some embodiments, the PAG includes triphenylsulfonium hexafluoroantimonate (Ph₃SSbF₆).

Another aspect of the present disclosure provides a method for reducing a horn shape of a spacer oxide, comprising providing an underlayer, forming a negative photoresist layer over the underlayer, creating a patterned photoresist layer and an expandable layer over the underlayer through an exposure process and a developing process, depositing a spacer oxide layer that covers both the patterned photoresist layer and the expandable layer, and performing a thermal process to expand the spacer oxide layer outward, thereby reducing the horn shape of the spacer oxide to be formed in subsequent processes. The negative photoresist layer comprises a polymer material, a suspension material, and a photoacid generator (PAG). The suspension material contains a plurality of expandable molecules, while the expandable layer comprise a plurality of released expandable molecules. The patterned photoresist layer is free of the released expandable molecules. The thermal process activates the released expandable molecules to expand outward, which in turn expands the spacer oxide layer outward.

In some embodiments, each of the plurality of expandable molecules is chemically bonded to the polymer material of the negative photoresist layer through a chemical bond.

In some embodiments, an expansion coefficient of the suspension material is greater than that of the polymer material.

In some embodiments, a density of the suspension material is less than that of the polymer material.

In some embodiments, the polymer material of the negative photoresist layer includes poly(tert-butoxycarboxystyrene) (PBOCSt).

In some embodiments, the PAG includes triphenylsulfonium hexafluoroantimonate (Ph₃SSbF₆).

In some embodiments, each of the plurality of released expandable molecules is separate from a polymer material of the patterned photoresist layer.

In some embodiments, a first sidewall of the expandable layer is coplanar with a first sidewall of the patterned photoresist layer, and a second sidewall of the expandable layer is coplanar with a second sidewall of the patterned photoresist layer.

In some embodiments, a method of photolytic bond cleavage is used to obtain the released expandable molecules.

Embodiments of present disclosure provide a negative photoresist that includes a suspension material containing a plurality of expandable molecules. Additionally, a method is presented for using the negative photoresist to reduce formation of spacer oxide horn shapes. By applying the negative photoresist and the associated method, numbers of steps and costs of the manufacturing process are reduced, and a yield of a manufacturing process is improved.

The foregoing has outlined rather broadly the features and technical advantages of the present disclosure in order that the detailed description of the disclosure that follows may be better understood. Additional features and advantages of the disclosure are described below, and form the subject of the claims of the disclosure. It should be appreciated by those skilled in the art that the conception and specific embodiments disclosed may be readily utilized as a basis for modifying or designing other structures or processes for carrying out the purposes of the present disclosure. It should also be realized by those skilled in the art that such equivalent constructions do not depart from the spirit and scope of the disclosure as set forth in the appended claims.

### BRIEF DESCRIPTION OF THE DRA WINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

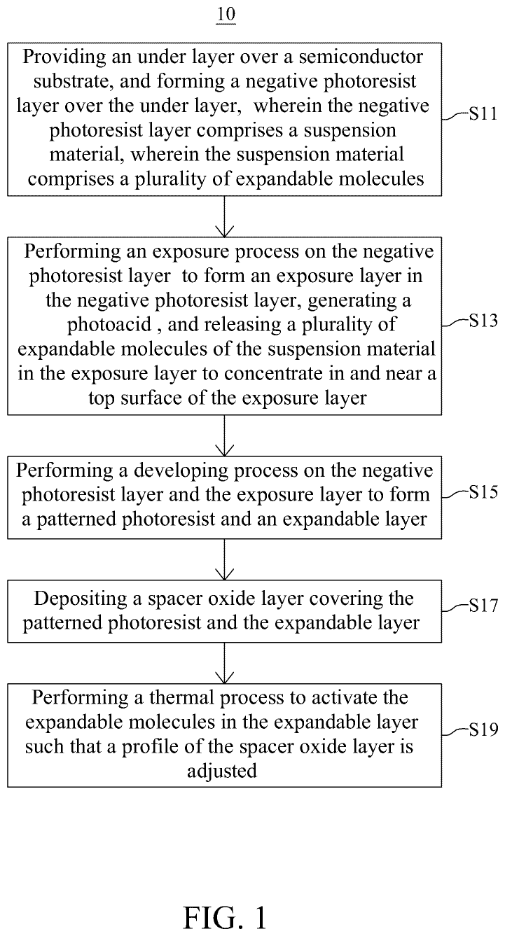

FIG. 1 is a flow diagram illustrating a method for reducing horn shapes of a spacer oxide in accordance with some embodiments of the present disclosure.

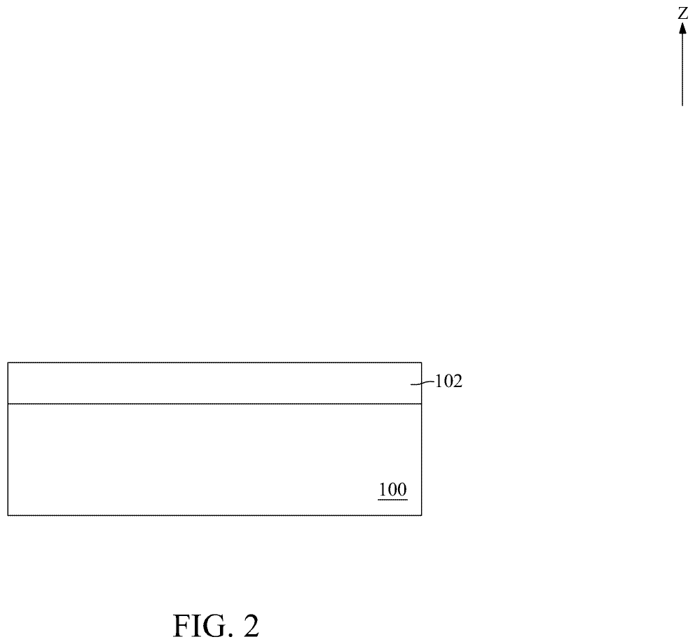

FIGS. 2 to 9 are schematic cross-sectional diagrams illustrating intermediate stages of a method for reducing horn shapes of a spacer oxide in accordance with some embodiments of the present disclosure.

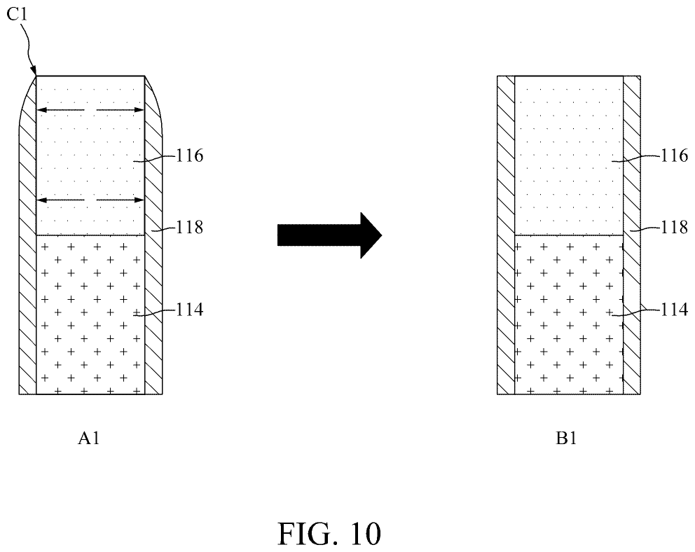

FIG. 10 is a schematic view illustrating the spacer oxide profiles before and after an adjustment in accordance with some embodiments of the present disclosure.

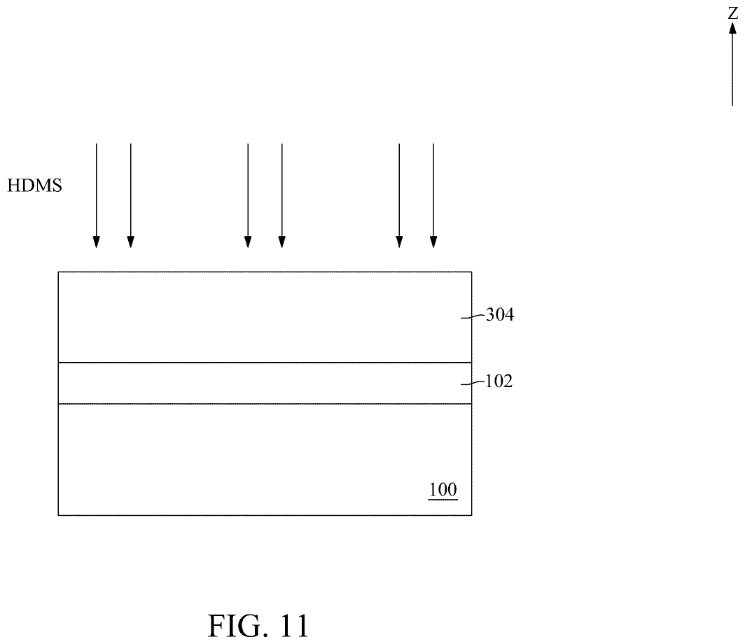

FIGS. 11 to 15 are schematic cross-sectional diagrams illustrating intermediate stages of a method for reducing horn shapes of a spacer oxide in accordance with a comparative embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures, do not necessarily mean an exactly identical orientation, layout, location, shape, size, amount, or other measure, but are intended to encompass nearly identical orientations, layouts, locations, shapes, sizes, amounts, or other measures within acceptable variations that may occur, for example, due to manufacturing processes. The term “substantially” may be used herein to reflect such meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the axis Z, and below (or down) corresponds to the opposite direction of the arrow of the axis Z.

FIG. 1 is a flow diagram illustrating a method 10 for reducing horn shapes of a spacer oxide in accordance with some embodiments of the present disclosure. FIGS. 2 to 9 are schematic cross-sectional diagrams illustrating intermediate stages of the method 10 in accordance with some embodiments of the present disclosure.

With reference to FIGS. 1 to 3, in step S11, a semiconductor substrate 100 and an underlayer 102 may be provided, and a negative photoresist layer 104 may be formed over the underlayer 102.

With reference to FIG. 2, in some embodiments, the semiconductor substrate 100 may include a bulk semiconductor substrate. The bulk semiconductor substrate may be formed of, for example, an elementary semiconductor, such as silicon or germanium; a compound semiconductor, such as silicon germanium, silicon carbide, gallium arsenide, gallium phosphide, indium phosphide, indium arsenide, indium antimonide, or other III-V compound semiconductor or II-VI compound semiconductor; or a combination thereof.

In some embodiments, the semiconductor substrate 100 may include a semiconductor-on-insulator structure consisting of, from bottom to top, a handle substrate, an insulator layer, and a topmost semiconductor material layer. The handle substrate and the topmost semiconductor material layer may be formed of a material same as a material of the bulk semiconductor substrate mentioned above. The insulator layer may be a crystalline or non-crystalline dielectric material, such as an oxide and/or a nitride. For example, the insulator layer may be a dielectric oxide such as silicon oxide. Alternatively, the insulator layer may be a dielectric nitride such as silicon nitride or boron nitride. Additionally, the insulator layer may comprise a stack of a dielectric oxide and a dielectric nitride, such as a stack of silicon oxide, silicon nitride, and/or boron nitride, in any order. The insulator layer may have a thickness between about 10 nm and about 200 nm.

It should be noted that, in the description of the present disclosure, the term “about,” when used to modify a quantity of an ingredient, component, or reactant, refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. In yet another aspect, the term “about” means within 10%, 9%, 8%, 7%, 6%, 5%, 4%, 3%, 2% or 1% of the reported numerical value.

With reference to FIG. 2, the underlayer 102 may be disposed over and cover the semiconductor substrate 100. The underlayer 102 can serve various purposes and may comprise different materials.

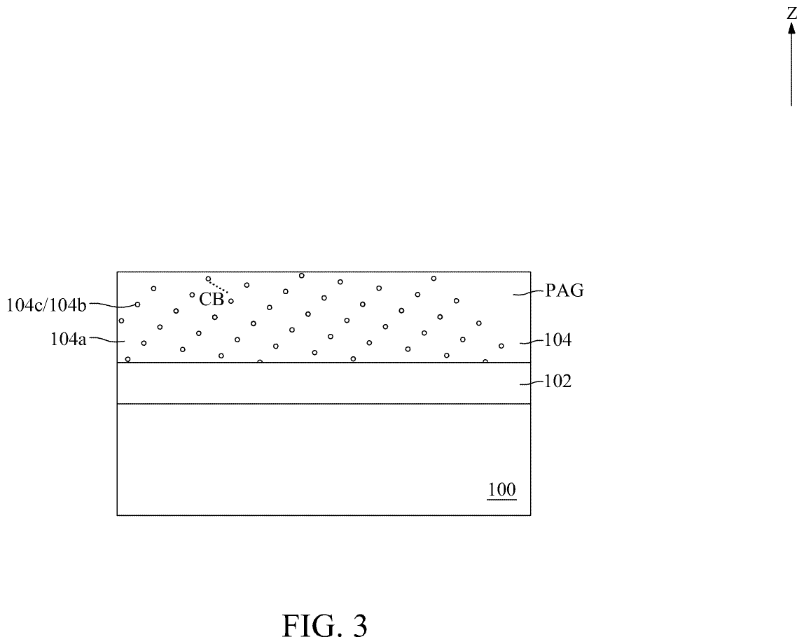

In some embodiments, the underlayer 102 enhances adhesion for subsequent coatings, such as the negative photoresist layer 104 shown in FIG. 3. This ensures a strong bond between the negative photoresist layer 104 and the semiconductor substrate 100, reducing a risk of delamination and defects.

Additionally, the underlayer 102 may fill surface irregularities of the semiconductor substrate 100, providing a flatter surface that results in better photoresist coating and development outcomes. The underlayer 102 may also improve optical performance during lithography processes, such as an exposure process 109, a developing process 117, and a post-exposure bake (PEB) process, ensuring uniformity and consistency of the negative photoresist layer 104 during exposure and development, thus enhancing pattern accuracy.

Furthermore, the underlayer 102 may act as an isolation layer, preventing interactions between different materials and ensuring stability in electrical performance. The underlayer 102 can also serve as a buffer layer, absorbing stresses that may occur during manufacturing, thereby protecting subsequent layers from damage. In certain deposition processes, the underlayer 102 may function as a seed layer, promoting growth or deposition of subsequent materials to ensure good crystal structure and performance. Lastly, the underlayer 102 may serve as a bottom anti-reflective coating (BARC) layer, reducing light reflection on a substrate surface and improving resolution and quality of lithographic patterns.

In some embodiments, the underlayer 102 may be formed of polymers, such as polyimide, polystyrene, PMMA, polyurethane, PEEK, or polyester oxides. In some embodiments, the underlayer 102 may be formed of silicon dioxide and silicon nitride. In some embodiments, the underlayer 102 may be formed of alumina (Al₂O₃). In some embodiments, the underlayer 102 may be formed of a low-k dielectric, such as silicon oxycarbide (SiOC), or a metal, such as titanium or tantalum.

With reference to FIG. 3, the negative photoresist layer 104 may be formed over and cover the underlayer 102. The negative photoresist layer 104 may comprise a polymer material 104a, a suspension material 104b, and a plurality of expandable molecules 104c.

In some embodiments, an expansion coefficient of the suspension material 104b is greater than that of the polymer material 104a. As a result, compared to photoresists without the suspension material 104b, the negative photoresist layer 104 may exhibit more expansive properties. Additionally, a density of the suspension material 104b is less than that of the polymer material 104a, which enhances suspension properties of the negative photoresist layer 104.

The polymer material 104a may comprise poly(tert-butoxycarboxystyrene) (PBOCSt). The suspension material 104b, containing the expandable molecules 104c, may be uniformly distributed throughout the negative photoresist layer 104. A chemical bond CB may form between the polymer material 104a and the expandable molecules 104c, which are protected by a tert-butyl group. Due to the presence of the expandable molecules 104c, the negative photoresist layer 104 is also referred to as the first expandable photoresist 104.

It should be noted that the first expandable photoresist 104 is a negative-tone photoresist (or a negative photoresist). In other words, during the exposure process, a photosensitive material of the first expandable photoresist 104 undergoes a chemical change, causing a material in exposed areas to become insoluble in a developer, while unexposed areas remain soluble. Typically, negative-tone photoresists exhibit high resolution, providing clearer edges in fabrication of fine patterns. In addition, negative-tone photoresists generally demonstrate good etch resistance during subsequent etching processes, effectively protecting underlying materials.

With reference to FIG. 3, a photoacid generator (PAG), such as triphenylsulfonium hexafluoroantimonate (Ph₃SSbF₆), may be introduced into the first expandable photoresist 104. Typically, PAGs are primarily used in processes involving positive photoresists. In positive photoresists, PAGs generate acid during an exposure process, thereby making certain areas of the photoresist more soluble in a developer, allowing for desired patterns. In contrast, negative photoresists work by making certain areas of the photoresist less soluble upon exposure. Therefore, PAGs are generally not used in negative photoresist processes.

However, in accordance with some embodiments of the present disclosure, the first expandable photoresist 104 comprises the suspension material 104b containing the plurality of expandable molecules 104c. This composition allows the PAGs to be used in the negative photoresist 104 to facilitate progression of process reactions; for example, the PAG is used to facilitate photolytic bond cleavage.

With reference to FIGS. 1, 4, and 5, in step S13, an exposure process 109 may be performed on the first expandable photoresist 104 to form an exposure layer 112 within the first expandable photoresist 104, and to release the expandable molecules 104c from the polymer material 104a of the first expandable photoresist 104.

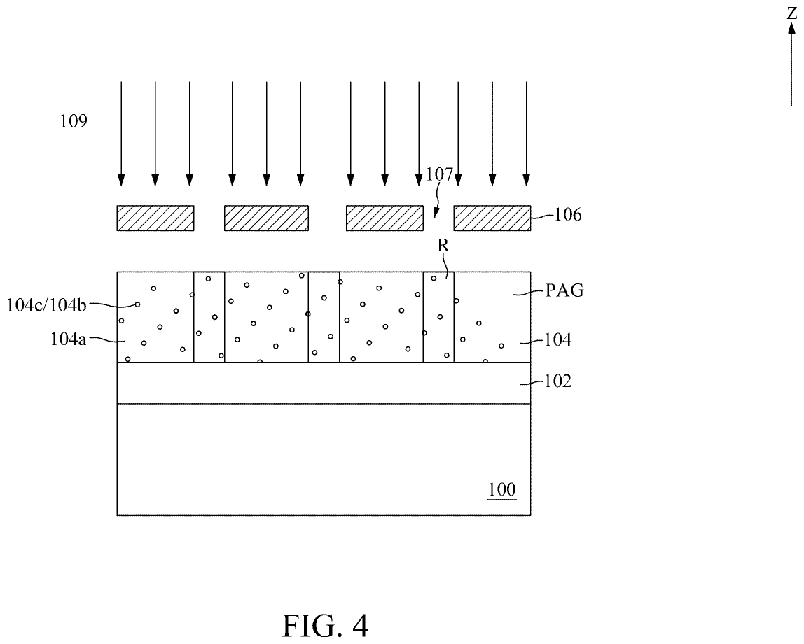

With reference to FIG. 4, during the exposure process 109, a mask (or reticle) 106 with an unmasked portion 107 may be disposed over the first expandable photoresist 104. The unmasked portion 107 defines a region R in the first expandable photoresist 104 that will be exposed. The region R is located where an exposure layer 112 will be formed in a subsequent process.

A light source, typically an ultraviolet or an extreme ultraviolet light, may be used for the exposure process 109. This includes deep ultraviolet (DUV) light with wavelengths ranging from 193 nanometers (nm) to 248 nm and an extreme ultraviolet (EUV) light with a wavelength of approximately 13.5 nm.

During the exposure process 109, when exposed to the light source, the PAG, such as triphenylsulfonium hexafluoroantimonate (Ph₃SSbF₆), decomposes and releases photoacids. These photoacids can catalyze subsequent chemical reactions, such as promoting deprotection or de-esterification reactions in the region R of the first expandable photoresist 104, thereby altering solubility and other properties of the first expandable photoresist 104 within the region R.

For example, as shown in equation 1 below, under light irradiation (hv) conditions, Ph₃SSbF₆ can undergo photolytic reactions, meaning that Ph₃SSbF₆ can decompose and generate other chemical species when exposed to light. Specifically, this reaction produces acidic species such as hydrosulfonic acid (HSbF₆) along with other byproducts. In other words, through the specific reaction mechanism, Ph₃SSbF₆ may release the acidic species HSbF₆.

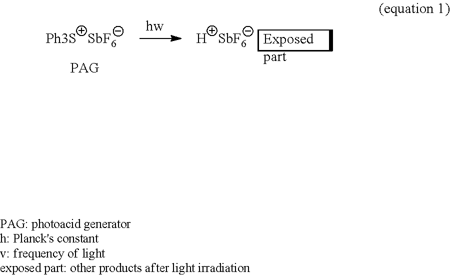

In addition, during the exposure process 109, the expandable molecules 104c in the region R may be released from the polymer material 104a of the first expandable photoresist 104. In other words, the chemical bonds CB, as shown in FIG. 3, between the polymer material 104a and the expandable molecules 104c are severed, allowing the expandable molecules 104c to move freely within the region R of the first expandable photoresist 104.

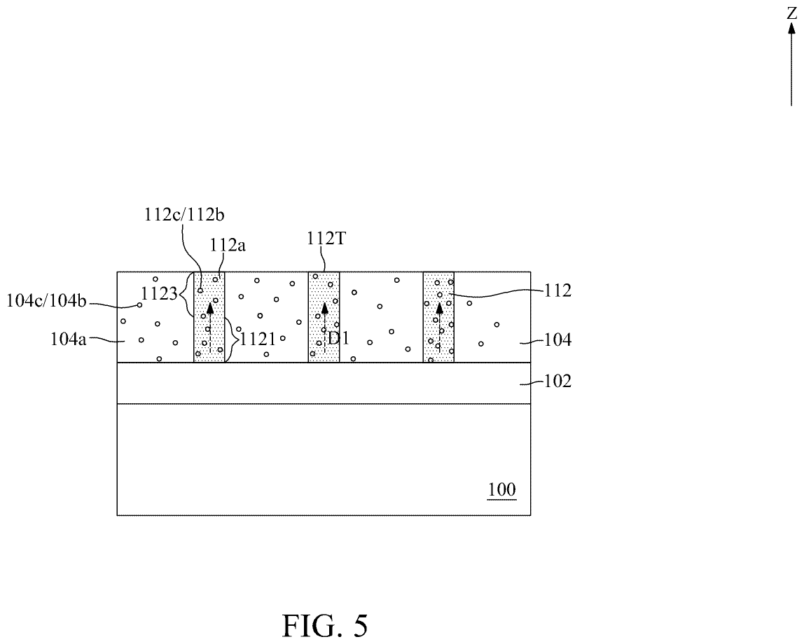

With reference to FIG. 5, during the exposure process 109, an exposure layer 112 in the first expandable photoresist 104 may be formed. In some embodiments, a method of photolytic bond cleavage, as shown in equation 2 below, may be used to continuously release the expandable molecules 104c from the polymer material 104a of the first expandable photoresist 104 and to form a plurality of expandable molecules 112c in the exposure layer 112.

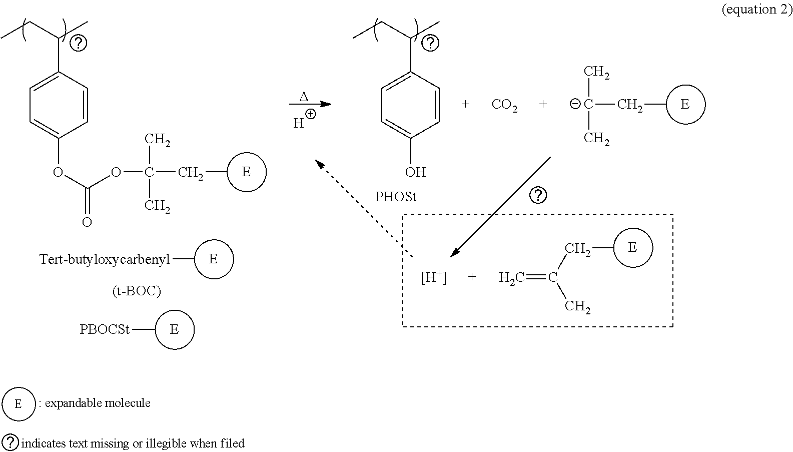

[symbol] : expandable molecule

As shown in equation 2, in some embodiments, under the influence of light, heat, and acid (H⁺), poly(tert-butoxycarboxystyrene) (PBOCSt), which is bonded with an expandable molecule [symbol] , may generate poly(4-hydroxystyrene) (PHOSt), carbon dioxide (CO₂), and an expandable molecule [symbol] protected by a butyl group. In this equation, the PBOCSt may serve as the polymer material 104a of the first expandable photoresist 104, while the expandable molecule [symbol] before the reaction in equation 2 may represent the suspension material 104b or the expandable molecule 104c of the first expandable photoresist 104.

The PHOSt may be the polymer material 112a of the exposure layer 112, and the expandable molecule [symbol] protected by a butyl group after the reaction in equation 2 may correspond to the suspension material 112b of the exposure layer 112. Additionally, the expandable molecule [symbol] may refer to the expandable molecule 112c.

In some embodiments, the PBOCSt, excluding the t-BOC group, may be the polymer material 104a of the first expandable photoresist 104, while the expandable molecule [symbol] bonded with the t-BOC group may be the suspension material 104b. Furthermore, the expandable molecule [symbol] before the reaction in equation 2 may represent the expandable molecule 104c of the first expandable photoresist 104. After the reaction in equation 2, the expandable molecule [symbol] may correspond to either the suspension material 112b or the expandable molecule 112c of the exposure layer 112.

Specifically, referring to equations 1 and 2, under light irradiation (hv) conditions, the photoacid generator (PAG) may produce a photoacid, such as HSbF₆, which contains hydrogen ions (H⁺) that can react with the polymer material 104a bonded to the expandable molecule 104c (e.g., PBOCSt and the expandable molecule [symbol] ). Under the catalysis of heat from the light source or an additional heating source, an exposure layer 112 may be formed, comprising a polymer material 112a (e.g., PBOCSt) and a suspension material 112b (e.g., the expandable molecule [symbol] protected by a butyl group after the reaction).

It should be noted that the PHOSt contains a hydroxyl group (—OH), which imparts significant hydrophilic (water-attracting) characteristics compared to the PBOCSt. Additionally, since the expandable molecule 112c and the polymer material 112a are not bonded, the expandable molecule 112c can move freely within the exposure layer 112.

Furthermore, during the reaction, the tert-butyl group continuously releases hydrogen ions (H⁺), which interact with the polymer material 104a bonded to the expandable molecules 104c, creating an amplification effect and facilitating multiple iterations to release more expandable molecules 112c. This process is referred to as the method of photolytic bond cleavage.

With reference to FIG. 5, during the exposure process 109, the exposure layer 112 may be formed at the location of the region R, which was previously defined by the unmasked portion 107 of the mask 106. The exposure layer 112 consists of a polymer material 112a and a suspension material 112b. In some embodiments, an expansion coefficient of the suspension material 112b is greater than that of the polymer material 112a. Consequently, compared to photoresists that do not contain the suspension material 112b, the exposure layer 112 exhibits more expansive properties.

In some embodiments, a density of the suspension material 112b is less than that of the polymer material 112a, resulting in the exposure layer 112 exhibiting enhanced suspension properties compared to photoresists without the suspension material 112b. The polymer material 112a may comprise poly(4-hydroxystyrene) (PHOSt), while the suspension material 112b may consist of a plurality of expandable molecules 112c.

Due to the presence of expandable molecules 112c in the exposure layer 112, the exposure layer 112 is also referred to as the second expandable photoresist 112. It should be noted that the expandable molecules 112c originate from the expandable molecules 104c in the region R. A key difference between the expandable molecule 104c and the expandable molecule 112c is that the former is bonded to the polymer material 104a, while the latter is not bonded to the polymer material 112a. This allows the expandable molecule 112c to move freely within the region R.

Because of its lower density, combined with the exposure process 109 that makes the second expandable photoresist 112 relatively more hydrophilic than the first expandable photoresist 104, as well as factors such as polarity, intermolecular forces, or capillary action, the expandable molecule 112c moves in a direction D1 and accumulates on a top surface 112T of the second expandable photoresist 112. This results in an upper portion 1123 of the second expandable photoresist 112 exhibiting thermal expansion characteristics, while a lower portion 1121 of the second expandable photoresist 112 is almost free of the expandable molecule 112c. After the exposure process 109 is performed, the mask 107 may be removed.

With reference to FIGS. 1, 6, and 7, in step S15, a developing process 117 may be performed on the first expandable photoresist 104 and the second expandable photoresist 112 to form a patterned photoresist 114 and an expanded layer 116.

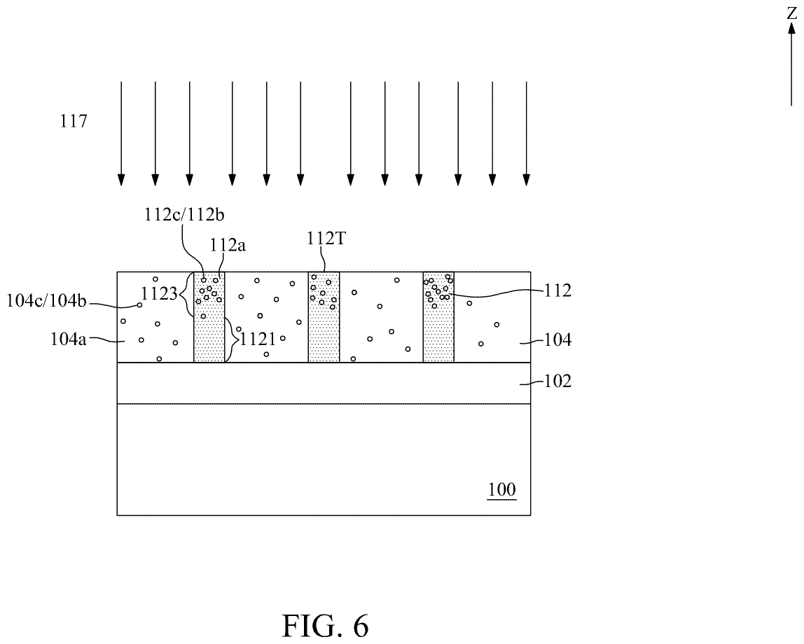

With reference to FIG. 6, the developing process 117 using a developer may be performed to develop the second photoresist layer 112, while the first photoresist layer 104 is removed accordingly. Since the first expandable photoresist 104 is a negative-tone photoresist, after the exposure process 109, unexposed portions of the first expandable photoresist 104 become soluble in the developer, resulting in the unexposed areas being removed. In contrast, the photosensitive portion, specifically the second photoresist layer 112, undergoes a cross-linking or polymerization reaction, rendering the exposed areas insoluble in the developer. Therefore, during the developing process 117, the exposed areas can be retained. In other words, the second photoresist layer 112 may be preserved during the developing process 117. In some embodiments, the developer may comprise potassium hydroxide (KOH), tetramethylammonium hydroxide (TMAH), or AZ 400K Series (AkzoNobel®) developer.

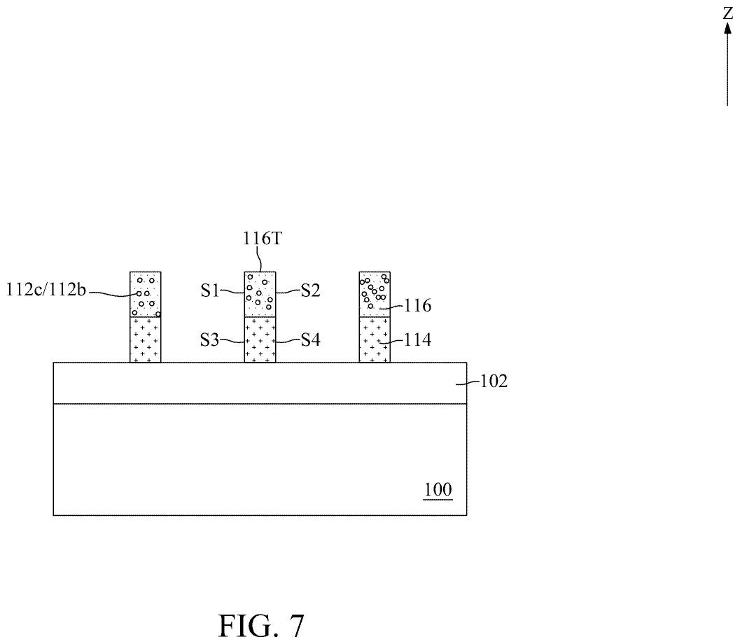

With reference to FIG. 7, after the developing process 117 is performed, a patterned photoresist 114 and an expandable layer 116 over the patterned photoresist 114 may be formed. The patterned photoresist 114 is formed from the lower portion 1121 of the second expandable photoresist 112, while the expandable layer 116 is formed from the upper portion 1123 of the second expandable photoresist 112. In some embodiments, after the developing process 117, a post-exposure bake (PEB) process may be performed to improve a chemical stability of the expandable layer 116 during subsequent processing, thereby reducing degradation. Additionally, the PEB process may enhance a resolution of the expandable layer 116 by promoting more uniform chemical reactions during thermal treatment, leading to clearer patterns. The PEB process may also assist in removing photoresist residue from the second expandable photoresist 112, ensuring cleaner patterns during the developing process. Furthermore, the PEB process may enhance adhesion between the expandable layer 116 and the patterned photoresist 114, as well as the semiconductor substrate 100, reducing the risk of delamination or defects in subsequent processing steps. Lastly, the PEB process may help improve a thickness uniformity of the expandable layer 116, ensuring consistent photolithographic results across an entire wafer.

As shown in FIG. 7, in some embodiments, the patterned photoresist 114 may comprise sidewalls S3 and S4, while the expandable layer 116 may comprise sidewalls S1 and S2. In some embodiments, the sidewall S1 of the expandable layer 116 may be coplanar with the sidewall S3 of the patterned photoresist 114. Similarly, the sidewall S2 of the expandable layer 116 may be coplanar with the sidewall S4 of the patterned photoresist 114. Additionally, in some embodiments, a top surface 116T of the expandable layer 116 may be coplanar with the top surface of 112T of the second expandable photoresist 112.

With reference to FIG. 7, since the expandable molecules 112c are concentrated in the upper portion 1123 of the second expandable photoresist 112, there are almost no expandable molecules 112c present in the patterned photoresist 114. In contrast, due to the method of photolytic bond cleavage and the amplification effect, the upper portion 1123 of the second expandable photoresist 112 contains a large number of expandable molecules 112c. As a result, the expandable layer 116 exhibits expandable properties.

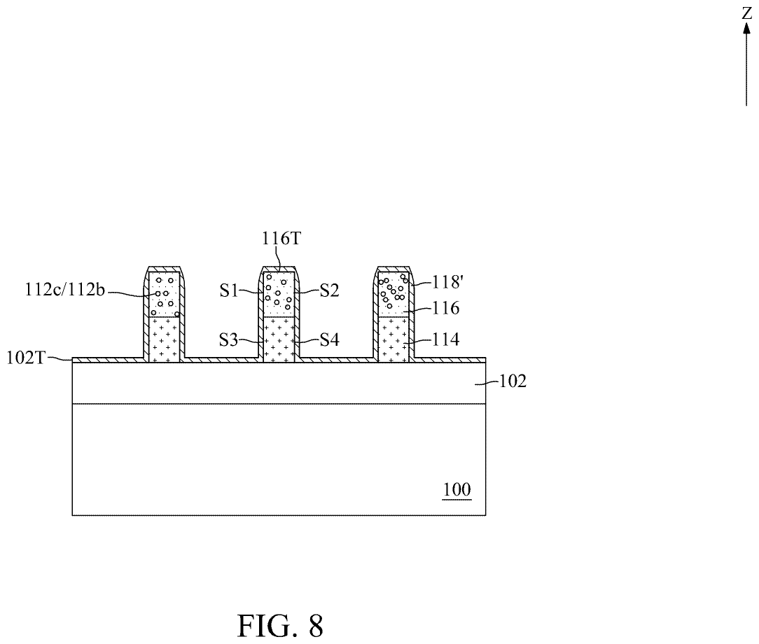

With reference to FIGS. 1 and 8, in step S17, a spacer oxide layer 118′ may be formed to cover the patterned photoresist 114 and the expandable layer 116.

With reference to FIG. 8, a deposition process may be performed to form the spacer oxide layer 118′. In some embodiments, the spacer oxide layer 118′ may be disposed on the sidewalls S1 and S2 of the expandable layer 116, as well as on the sidewalls S3 and S4 of the patterned photoresist 114. Additionally, the spacer oxide layer 118′ may be disposed on the top surface 102T of the underlayer 102 and the top surface 116T of the expandable layer 116. The deposition of the spacer oxide layer 118′ may involve a chemical vapor deposition (CVD) process, a physical vapor deposition (PVD) process, an electroplating process, an atomic layer deposition (ALD) process, a spin coating process, or similar methods. The spacer oxide layer 118′ may be formed from materials such as silicon dioxide, alumina, or titanium dioxide, as well as silicon nitride, zirconium dioxide, indium oxide, zinc oxide, or other suitable materials. In some embodiments, the spacer oxide layer 118′ may be a single layer or may comprise a multi-layer structure.

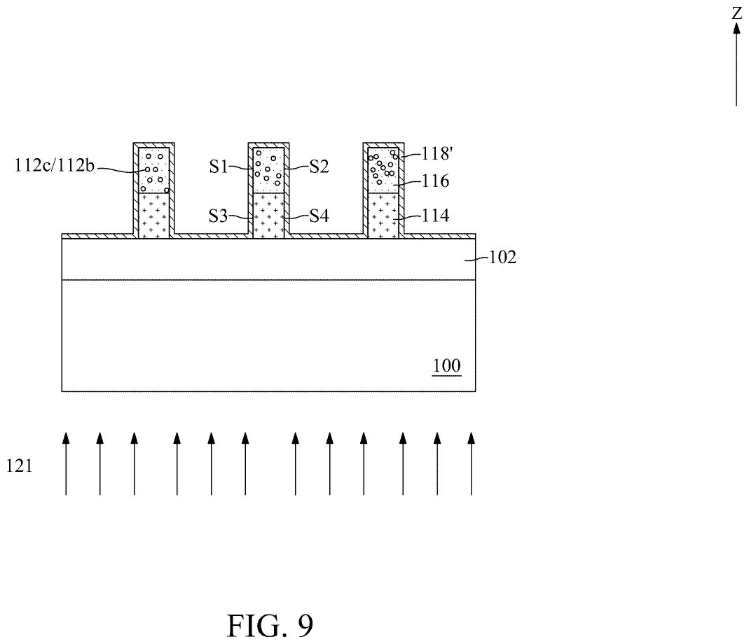

With reference to FIGS. 1 and 9, in step S19, a thermal process 121 is performed to adjust a profile of the spacer oxide layer 118′.

With reference to FIG. 9, the thermal process 121 may increase a temperature of the expandable layer 116, so as to activate and expand the expandable molecules 112c within the expandable layer 116. During the expansion process, the expandable molecules 112c may expand outward, causing the spacer oxide layer 118′ of the expandable layer 116 to also expand outward. As a result, a shape of the spacer oxide layer 118′ is adjusted, helping to avoid formation of a horn shape C1 of the spacer oxide 118, as shown in FIG. 10, in subsequent processes.

It should be noted that an expansion coefficient of the suspension material 112b of the second expandable photoresist 112, which comprises the expandable molecules 112c, is greater than an expansion coefficient of the polymer material 112a of the second expandable photoresist 112. As a result, the upper portion 1123 of the second expandable photoresist 112 may expand more than the lower portion 1121 of the second expandable photoresist 112. In other words, the expanded layer 116 may expand more than the patterned photoresist 114. Therefore, a desired profile, such as one where the upper and lower portions have the same width, resembling a rectangular profile, can be formed.

FIG. 10 is a schematic view illustrating spacer oxide profiles before and after adjustment in accordance with some embodiments of the present disclosure.

With reference to FIG. 10, profile A1 and profile B1 represent the profiles of a spacer oxide before and after adjustment, respectively. Each of the profiles A1 and B1 may comprise a spacer oxide disposed on sidewalls of a patterned photoresist (a lower portion) and on sidewalls of an expanded layer (an upper portion) above a patterned photoresist. The profiles A1 and B1 may be formed by a subsequent process, such an etching process, following the method 10 described above.

As shown in FIG. 10, horn shape(s) C1 may be formed at a top of the spacer oxide 118. It should be noted that the profile A1 is merely a schematic representation. From the profile A1, it appears that the horn shape(s) may be not very pronounced. In some embodiments, especially under specifications requiring small line widths and tight spacing, the horn shape(s) will become more pronounced during complex processes (e.g., a pitch doubling process). This situation may lead to a decrease in yield in subsequent processes.

As a result, the disclosure provides a method that utilizes the expandable properties of expandable molecules to push the spacer oxide layer outward, aiming to achieve the desired profile, such as the profile B1, as specified in the design. This approach can enhance yield of subsequent processes and reduce a number of process steps.

FIGS. 11 to 15 are schematic cross-sectional diagrams illustrating intermediate stages of a method for reducing horn shapes of a spacer oxide in accordance with a comparative embodiment of the present disclosure.

With reference to FIG. 11, in accordance with a comparative embodiment, a semiconductor substrate 100 and an underlayer 102 may be provided, and a photoresist layer 304 may be formed on the underlayer 102. The semiconductor substrate 100 and the underlayer 102 are same as or similar to the semiconductor substrate 100 and the underlayer 102 illustrated in FIG. 2, and repeated descriptions are omitted. The photoresist layer 304 may be either a positive-tone photoresist (or a positive photoresist) or a negative-tone photoresist (or a negative photoresist). Notably, the photoresist layer 304 does not contain any expandable molecules. Before proceeding to the next process, a first coating process is performed to spray hexamethyldisilazane (HDMS) onto the photoresist layer 304. The use of HDMS can enhance a performance of photoresist layer 304, improving stability thereof during exposure and developing processes. Additionally, in high-resolution semiconductor manufacturing, achieving line/space (L/S) ratios and critical dimensions (CD) of less than 50 nanometers necessitates use of a thin photoresist layer.

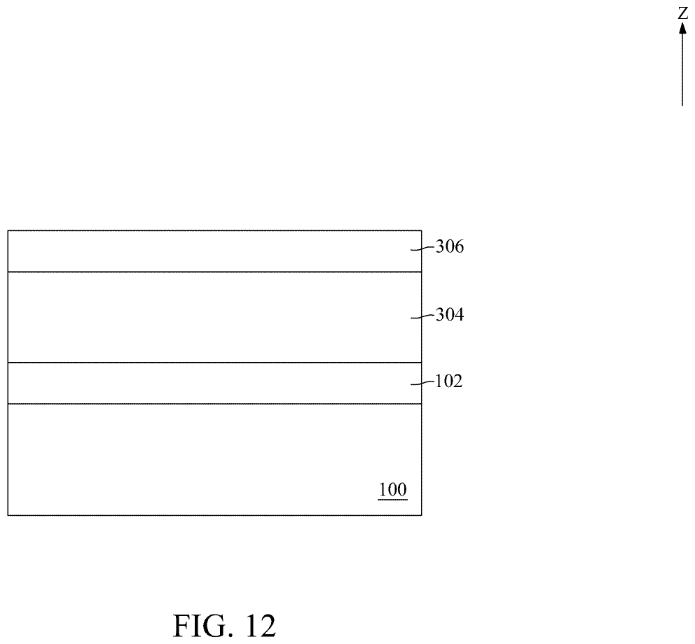

With reference to FIG. 12, in accordance with a comparative embodiment, a second coating process is performed to deposit a layer of light-transmitting expandable material 306 over and covering the photoresist layer 304. In some embodiments, the light-transmitting expandable material 306 may comprise polyester films, such as polyethylene terephthalate (PET), polycarbonate, or silicon-based materials.

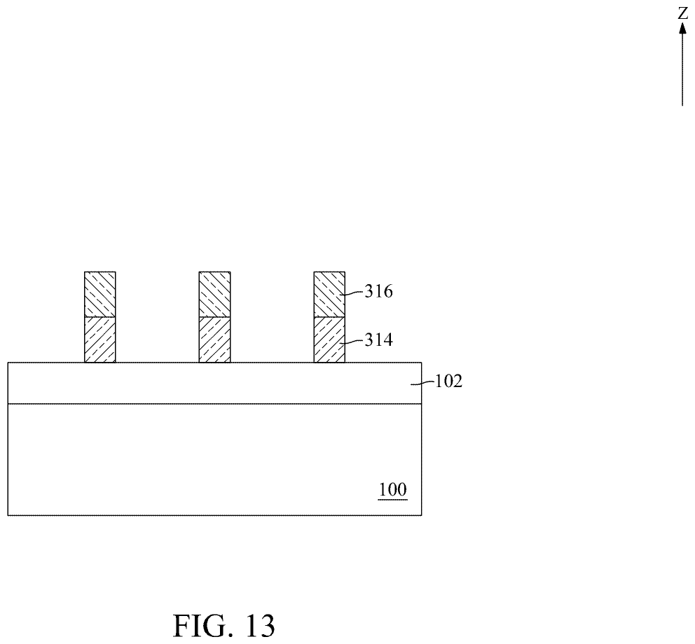

With reference to FIG. 13, in accordance with a comparative embodiment, an exposure process followed by a subsequent developing process may be performed to create a desired pattern over the underlayer 102. In some embodiments, after the exposure process, a post-exposure bake (PEB) process may be conducted. The exposure, developing, and post-exposure bake processes are similar to those described in the method 10 illustrated in FIGS. 4 to 6, and repeated descriptions are omitted. The pattern formed on the underlayer 102 may consist of a photoresist layer 314 and an expandable layer 316 disposed above the photoresist layer 314.

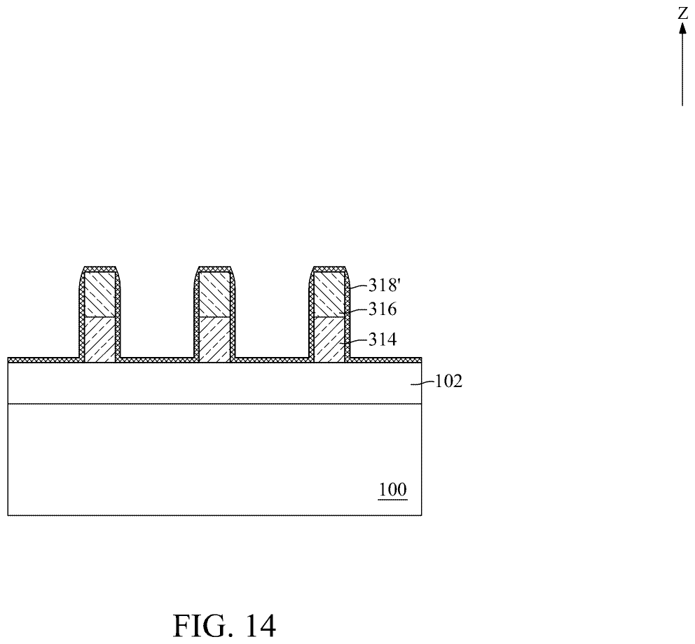

With reference to FIG. 14, in accordance with a comparative embodiment, a spacer oxide layer 318′ may be formed over and covering the pattern. The formation and materials of the spacer oxide layer 318′ are same as or similar to those of the spacer oxide layer 118′ in FIG. 8, and repeated descriptions are omitted.

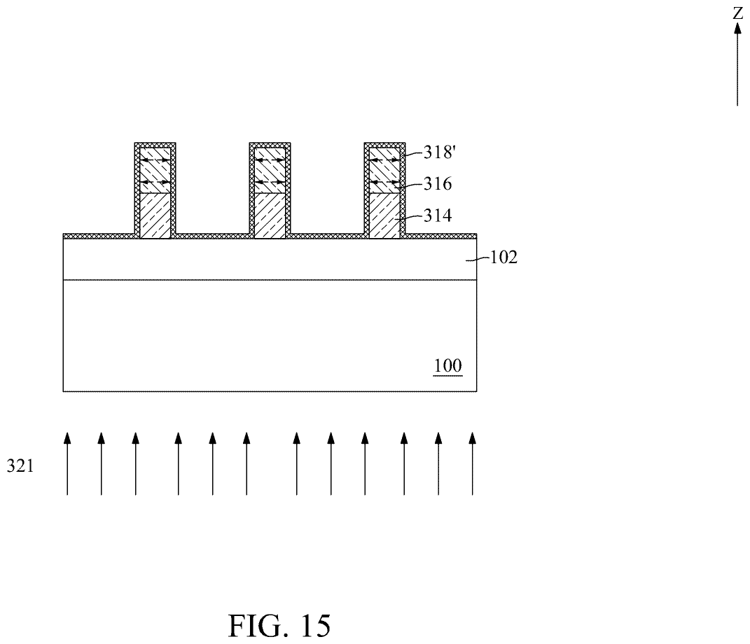

With reference to FIG. 15, in accordance with a comparative embodiment, a thermal process 321 is performed to raise a temperature of the expandable layer 316 in order to adjust a profile of the spacer oxide layer 318′. The thermal process 321 is same as or similar to the thermal process 121 in FIG. 9, and repeated descriptions are omitted.

As described above, in the comparative embodiment, two coating processes, including an HDMS coating process and a light-transmitting expandable material 316 coating process, are required to adjust the profile of the spacer oxide layer 318′. In contrast, the first expandable photoresist 104 in the disclosed embodiment provides a suspension material 104b that contains a plurality of expandable molecules 104c. During the exposure process 109, the expandable molecules 112c, originating from the releasing of the expanding molecules 104c, can accumulate at the top surface of the exposure layer 112. Heat activates the expanding molecules 112c, causing the suspension material 112b to expand outward in order to adjust the profile A1 of the spacer oxide layer 118′, thereby avoiding the formation of horn shape(s) C1 in the spacer oxide 118 during subsequent processes.

Embodiments of the present disclosure provide a negative photoresist 104 that includes a suspension material 104b containing a plurality of expandable molecules 104c. Additionally, the method 10 is provided for using the negative photoresist 104 to reduce the formation of spacer oxide horn shape(s) C1. Through the application of the negative photoresist 104 and the method 10, the numbers of steps and costs in the manufacturing process are reduced, while a yield of the manufacturing process is improved.

One aspect of the present disclosure provides an expandable negative photoresist comprising a polymer material, a suspension material, and a photoacid generator (PAG). The suspension material contains a plurality of expandable molecules.

In some embodiments, an expansion coefficient of the suspension material is greater than that of the polymer material.

In some embodiments, a density of the suspension material is less than that of the polymer material.

In some embodiments, the expandable molecule is chemically bonded to the polymer material through a chemical bond.

In some embodiments, the chemical bond is severed using a photolytic bond cleavage method.

In some embodiments, the polymer material includes poly(tert-butoxycarboxystyrene) (PBOCSt).

In some embodiments, the PAG includes triphenylsulfonium hexafluoroantimonate (Ph₃SSbF₆).

Another aspect of the present disclosure provides a method for adjusting a profile of a spacer oxide, comprising providing a substrate, applying an underlayer over the substrate, forming a first photoresist layer over the underlayer, performing an exposure process on the first photoresist layer to create a second photoresist layer in the first photoresist layer, conducting a developing process on both the first and second photoresist layers to form a third photoresist layer and an expandable layer over the third photoresist layer, depositing a spacer oxide layer that covers both the third photoresist layer and the expandable layer, and performing a thermal process on the expandable layer, thereby adjusting the profile of the spacer oxide. The first photoresist layer comprises a first suspension material that contains a plurality of first expandable molecules, while the second photoresist layer comprises a second suspension material that contains a plurality of second expandable molecules. The expandable layer comprises the plurality of second expandable molecules. The thermal process is performed by activating the second expandable molecules in the expandable layer

In some embodiments, the first photoresist layer is a negative-tone photoresist.

In some embodiments, the first suspension material is uniformly distributed throughout the first photoresist layer.

In some embodiments, each of the plurality of first expandable molecules is chemically connected to a first polymer material in the first photoresist layer through a chemical bond.

In some embodiments, an expansion coefficient of the first suspension material is greater than that of the first polymer material.

In some embodiments, a density of the first suspension material is less than that of the first polymer material.

In some embodiments, the first polymer material of the first photoresist layer includes poly(tert-butoxycarboxystyrene) (PBOCSt).

In some embodiments, each of the plurality of second expandable molecules is separate from a second polymer material in the second photoresist layer.

In some embodiments, an expansion coefficient of the second suspension material is greater than that of the second polymer material.

In some embodiments, a density of the second suspension material is less than that of the second polymer material.

In some embodiments, the second polymer material of the second photoresist layer includes poly(4-hydroxystyrene) (PHOSt).

In some embodiments, the third photoresist layer is free of the second expandable molecules, while the expandable layer contains the second expandable molecules.

In some embodiments, the method further comprises disposing a mask over the first photoresist layer, wherein the mask includes an unmasked portion that defines a region of the first photoresist layer to be subsequently exposed.

In some embodiments, the exposure process is performed using an ultraviolet (UV) light.

In some embodiments, the first photoresist layer also includes a photoacid generator (PAG).

In some embodiments, the PAG includes triphenylsulfonium hexafluoroantimonate (Ph₃SSbF₆).

Another aspect of the present disclosure provides a method for reducing a horn shape of a spacer oxide, comprising providing an underlayer, forming a negative photoresist layer over the underlayer, creating a patterned photoresist layer and an expandable layer over the underlayer through an exposure process and a developing process, depositing a spacer oxide layer that covers both the patterned photoresist layer and the expandable layer, and performing a thermal process to expand the spacer oxide layer outward, thereby reducing the horn shape of the spacer oxide to be formed in subsequent processes. The negative photoresist layer comprises a polymer material, a suspension material, and a photoacid generator (PAG). The suspension material contains a plurality of expandable molecules, while the expandable layer comprises a plurality of released expandable molecules. The patterned photoresist layer is free of the released expandable molecules. The thermal process activates the released expandable molecules to expand outward, which in turn expands the spacer oxide layer outward.

In some embodiments, each of the plurality of expandable molecules is chemically bonded to the polymer material of the negative photoresist layer through a chemical bond.

In some embodiments, an expansion coefficient of the suspension material is greater than that of the polymer material.

In some embodiments, a density of the suspension material is less than that of the polymer material.

In some embodiments, the polymer material of the negative photoresist layer includes poly(tert-butoxycarboxystyrene) (PBOCSt).

In some embodiments, the PAG includes triphenylsulfonium hexafluoroantimonate (Ph₃SSbF₆).

In some embodiments, each of the plurality of released expandable molecules is separate from a polymer material of the second photoresist layer.

In some embodiments, a first sidewall of the expandable layer is coplanar with a first sidewall of the patterned photoresist, and a second sidewall of the expandable layer is coplanar with a second sidewall of the patterned photoresist.

In some embodiments, a method of photolytic bond cleavage is used to obtain the released expandable molecules.

Embodiments of the present disclosure provide a negative photoresist that includes a suspension material containing a plurality of expandable molecules. Additionally, a method is presented for using the negative photoresist to reduce the formation of spacer oxide horn shapes. By applying the negative photoresist and the associated method, numbers of steps and costs in a manufacturing process are reduced, and a yield of the manufacturing process is improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A method for reducing a horn shape of a spacer oxide, comprising:
providing an underlayer;
forming a negative photoresist layer over the underlayer, wherein the negative photoresist layer comprises a polymer material, a suspension material containing a plurality of expandable molecules, and a photoacid generator (PAG);
creating a patterned photoresist layer and an expandable layer over the underlayer through an exposure process and a developing process, wherein the expandable layer comprises a plurality of released expandable molecules, while the patterned photoresist layer is free of the released expandable molecules;
depositing a spacer oxide layer that covers both the patterned photoresist layer and the expandable layer; and
activating the released expandable molecules by a thermal process to expand the released expandable molecules outward, which in turn expands the spacer oxide layer outward, thereby reducing the horn shape of the spacer oxide to be formed in subsequent processes.

2. The method of claim 1, wherein each of the plurality of expandable molecules is chemically bonded to the polymer material of the negative photoresist layer through a chemical bond.

3. The method of claim 2, wherein an expansion coefficient of the suspension material is greater than that of the polymer material.

4. The method of claim 3, wherein a density of the suspension material is less than that of the polymer material.

5. The method of claim 4, wherein the polymer material of the negative photoresist layer includes poly(tert-butoxycarboxystyrene) (PBOCSt).

6. The method of claim 5, wherein the PAG includes triphenylsulfonium hexafluoroantimonate (Ph₃SSbF₆).

7. The method of claim 1, wherein each of the plurality of released expandable molecules is separate from a polymer material of the patterned photoresist layer.

8. The method of claim 1, wherein a first sidewall of the expandable layer is coplanar with a first sidewall of the patterned photoresist, and a second sidewall of the expandable layer is coplanar with a second sidewall of the patterned photoresist.

9. The method of claim 1, wherein a method of photolytic bond cleavage is used to obtain the released expandable molecules.
